(19) United States
(12) Patent Application Publication
(10) Pub. No.: US 2005/0194038 A1
(43) Pub. Date: Sep. 8, 2005

(54) Electrodes for optoelectronic components and the use thereof

(76) Inventors: Christoph Brabec, Linz (AT); Jens Hauch, Erlangen (DE)

Correspondence Address: FISH & RICHARDSON PC, 225 FRANKLIN ST, BOSTON, MA, 02110, US

(21) Appl. No.: 10/986,686

(22) Filed: Nov. 12, 2004

Related U.S. Application Data
(63) Continuation-in-part of application No. PCT/DE03/01914, filed on Jun. 10, 2003.

(30) Foreign Application Priority Data
Jun. 13, 2002 (DE) 102 26 366.3

(51) Int. Cl. H01L 31/00

(52) U.S. Cl. 136/256; 257/431

(57) ABSTRACT

Electrodes are disclosed that can include allotropes, such as spherical allotropes. Examples of allotropes include silicon and/or carbon nanotubes. The electrodes can be used, for example, in organic semiconductor technology. The electrodes can contain either allotropes alone and/or allotropes that are embedded in an material. Examples of such materials are organic materials, such as one or more organic functional polymers.

### CROSS-REFERENCE TO RELATED APPLICATIONS

This application is a continuation-in-part of and claims priority under 35 U.S.C. § 120 to PCT/DE03/01914, filed Jun. 10, 2003, which claims priority to German patent application 102 26 366.3, filed Jun. 13, 2002. The contents of these applications is incorporated by reference herein.

### TECHNICAL FIELD

The invention relates to electrodes that include spherical allotropes, such as silicon and/or carbon nanotubes, and to the use thereof in organic semiconductor technology.

### BACKGROUND

Electrodes for optoelectronic components based on organic conductors such as, for example, PANI, PEDOT:PSS (polystyrene sulfonic acid) are disclosed in DE 101 268 59.9.

Derivatized nanotubes and spherical allotropes for use in (opto)electronic components are disclosed in DE 101 53 316.0.

### SUMMARY

It can be desirable to further enhance the conductivity, transparency to light, electronic work function and/or surface quality of electrodes. It is believed that, in certain instances, there may be a desire to devise new and better organic-based electrodes for use in so-called areas of electronics that implement semiconductor technology with materials other than the conventional ones such as silicon, germanium and the like.

In one aspect, the invention features an electrode that includes an allotrope. The electrode can be designed for use in an optoelectronic device. The electrode can be designed for use in a semiconductor device.

In another aspect, the invention features a photovoltaic cell that includes an electrode including a first allotrope.

In a further aspect, the invention features a photovoltaic cell that includes an electrode that includes nanotubes, a second electrode and an organic semiconductor between the electrodes.

In an additional aspect, the invention features a photovoltaic cell that includes an electrode that includes silicon, a second electrode and an organic semiconductor between the electrodes.

The electrode can be a cathode or an anode.

The electrode can be semitransparent or transparent.

The optical properties of the electrode can be adjusted by adjusting the length of the allotrope used.

The electrode can further include at least one organic functional polymer.

The electrode can further include an organic material, such as a conductive organic material. The organic material can be a semiconductor. The organic material can be a polymer.

The allotrope can be metallically conductive or semiconductive.

The allotrope can be present in the form a composite material.

The allotrope can be a nanotube, such as a carbon nanotube.

The allotrope can be silicon.

The allotrope can be a spherical allotrope.

The photovoltaic cell can further include a substrate that supports the first allotrope.

The photovoltaic cell can include an additional electrode that includes an allotrope.

The photovoltaic cell can include a organic semiconductor between the first and second electrodes.

In some embodiments, the electrode has improved (opto)electronic properties for organic semiconductor components and optoelectronic components.

The invention is directed to an electrode for optoelectronic and/or organic semiconductor elements that comprises allotropes.

In some embodiments, allotropes can be combined with organic conductors or semiconductors (typically conjugated polymers) to form a semitransparent or nontransparent electrode.

### DETAILED DESCRIPTION

The allotropes can be present in the electrodes in either metallically conductive or semiconductive form. Examples of metallically conductive allotropes are known, for example, from the literature (Z. F. Ren, Z. P. Huang, J. W. Xu, D. Z. Wang, J. H. Wang, L. Clavet, J. Chen, J. F. Klemic and M. A. Reed, “Large arrays of well-aligned carbon nanotubes,” Proceedings of 13th International Winter School on Electronic Properties of Novel Materials (1999), pp. 263-267).

Nanotubes can have many unique electronic, optical and mechanical properties. Single-walled nanotubes can have a high expansion resistance and can be metallic, semiconductive or insulative, depending on their diameter and chirality. For these properties to be used in nanotechnological applications, chemical derivatization of nanutubes may also be advisable, because this can improve their solubility and processability. In particular, the derivatized and/or dissolved nanotubes can be used as part of a phase mixture in organic functional polymers for microelectronics.

Spherical allotropes such as nanotubes are described, for example, in Nature 354 (1991), pp. 56-58. Examples include silicon and carbon nanotubes.

The allotropes can either be added to conductive organic materials and/or grown on substrates by pulling. The electrodes can be made either with metallic allotropes alone or with composite materials comprising metallic allotropes and/or semiconductive allotropes.

The following allotropes can be suitable for positive/negative electrodes, and can be formed by first depositing a suitable catalyst on substrates such as glass, metal (molybdenum), semiconductors (silicon) or films (PET). Also suitable for positive/negative electrodes are a combination of at least two items selected from the group including substrates (e.g., conductive oxides, such as ITO), doped semiconductors (e.g., silicon, germanium), metals such as Al and Ag, or nonconductive substrates (e.g., glass, films) to which allotropes are applied either in purest form or in mixtures with conductive or nonconductive binding materials (e.g., polymers).

The term “organic material” or “functional polymer” or “polymer” as used herein encompasses all types of organic, metalorganic and/or organic/inorganic synthetic materials (hybrids), including plastics. This includes all types of materials except for the semiconductors that form conventional diodes (germanium, silicon) and typical metallic conductors. Hence, there is no intention to limit the term in the dogmatic sense to organic material as carbon-containing material, but rather, the broadest use of silicon-containing materials, for example, is contemplated. Furthermore, the term is not to be construed as limited with respect to molecular size, particularly to polymeric and/or oligomeric materials, but instead the use of “small molecules” is completely feasible. The word “polymer” in “functional polymer” is historically derived and makes no statement as to the presence of any actual polymeric compound. Functional polymers can mean semiconducting, conducting and/or insulating materials.

Metallic allotropes or nanotubes grown (formed) on a substrate can produce conductive electrodes that have a three-dimensional structure, for example a two-dimensional array with nanotubes of large surface area standing thereon. The increase in surface area, i.e., the ratio of the surface area of the substrate to which the allotrope is applied to the usable surface area of the electrode, i.e., the active area, can be increased via the density of the “planting,” i.e., of the allotropes grown, and/or via their length.

Composite materials for electrodes can be produced, for example, by embedding metallic allotropes in a matrix of conductive functional polymer. In this mixture of allotropes with the organic functional polymer, the conductivity and/or transparency of the electrode can be optimized via the amount of allotrope and its concentration in the matrix. From this composite material, for example in the form of a solution, an electrode can be forced.

Semiconductive allotropes, in particular, can also be used as a positive electrode (electron acceptor) in heterojunction applications. It has recently been shown that composites containing nanotubes with conjugated polymers exhibit a strong photoeffect (S. B. Lee, T. Karayama, H. Kajii, H. Araki and K. Yoshino, Synth. Met. 121 (2001), 1591-1592).

For optoelectronic components such as, for example, organic light-emitting diodes (OLEDs), as well as organic solar cells and photodetectors, the optical properties of the electrodes can be adapted by varying the length of the allotrope. Allotropes or nanotubes of suitable length function like a λ/4 antenna, which is used to absorb electromagnetic radiation. For example, allotropes 100 to 200 nm in length are used to achieve absorption in the visible wavelength range (400-800 nm).

The following examples are illustrative and non-limiting.

Example 1 is an organic solar cell or organic photodetector, based on a metallic nanotube electrode. First, either the nanotubes are deposited on a conductive substrate or, as an alternative, they can be grown, i.e., formed by allowing them to grow, on a nonconductive substrate. For contacting, the nanotube electrodes are coated (e.g. by a process of forcing out of solution) with a conductive (where appropriate or optionally, a semitransparent) polymer. This electrode then includes the following layers: substrate; optionally a conductive layer (e.g. Au, ITO, Al); nanotubes (specifically adjustable length and arrangement); and optionally a conductive polymer. The organic semiconductor (or a mixture of organic p-type and n-type semiconductors) is deposited (for example by a process of forcing out of solution) on this electrode. The component is completed by the application of a counterelectrode (typically by thermal vapor deposition of a thin metal layer). The optical absorption can be increased by suitable selection of the length of the nanotubes and their arrangement.

The second example is an organic solar cell or an organic photodetector based on a semiconductive nanotube electrode. For contacting, either the nanotubes are deposited on a conductive substrate or, as an alternative, they can be grown on a nonconductive substrate. For contacting, the nanotubes are coated (e.g. by a process of forcing out of solution) with a conductive (optionally semitransparent) polymer. The organic semiconductor (preferably a p-type semiconductor) is deposited (typically by a process of forcing out of solution) on this electrode (consisting of substrate/(optionally conductive layer, e.g. Au, ITO, Al)/nanotube/(optionally conductive polymer)). The semiconductive nanotubes of the electrode function as n-type semiconductors, thereby creating a photoeffect between the polymer semiconductor and the nanotubes. The component is completed by the application of a counterelectrode (typically by thermal vapor deposition of thin metal layers). The optical absorption can be increased by suitable selection of the nanotube length and the arrangement of the nanotubes.

The third example is an organic light-emitting diode (or an organic display) based on a nanotube electrode (nanotube electrode array). For contacting, either the nanotubes are deposited on a conductive substrate or, as an alternative, they can be grown on a nonconductive substrate for contacting, the nanotube electrode is coated (e.g. by a process of forcing out of solution) with a conductive (optionally semitransparent) polymer. The organic semiconductor (preferably a p-type semiconductor) is deposited (typically by a process of forcing out of solution) on this electrode (consisting of substrate/(optionally conductive layer, e.g. Au, ITO, Al)/nanotube/(optionally conductive polymer)). The component is completed by the application of a counterelectrode (typically by thermal vapor deposition of thin metal layers).

Finally, the contacting of an organic solar cell, an organic light-emitting diode or an organic photodetector is further prepared by pressing with a carbon nanotube electrode. Here, the semiconductor component can be constructed as follows. The bottom side is fabricated (substrate/electrode 1 (metal)/organic semiconductor), and the grown nanotube electrode is grown into the organic semiconductor. The pressing forces the carbon nanotubes into the organic semiconductor, completing the contacting. With this technology, either the electrode 1 or the nanotube electrode can be implemented as semitransparent.

The invention relates to electrodes that comprise spherical allotropes, particularly silicon and/or carbon nanotubes, and to the use thereof in organic semiconductor technology. The electrodes can contain either allotropes alone and/or allotropes that are embedded in an organic functional polymer.

In some embodiments, one of the electrodes in a photovoltaic cell can be a mesh electrode. Mesh electrodes are described, for example, in published U.S. patent applications 2003-0230337 and 2004-0187911, and published international patent WO03/041177. These applications are incorporated by reference herein.

Other embodiments are in the claims.

1. An electrode comprising an allotrope, wherein the electrode is designed for use in an optoelectronic device.

2. The electrode of claim 1, wherein the electrode is designed for use in a photovoltaic cell.

3. The electrode of claim 1, wherein the electrode is designed for use in a semiconductor device.

4. The electrode of claim 1, wherein the allotrope is metallically conductive or semiconductive.

5. The electrode of claim 1, wherein the allotrope is present in the form a composite material.

6. The electrode of claim 1, wherein the electrode is semitransparent or transparent.

7. The electrode of claim 1, wherein the allotrope comprises a nanotube.

8. The electrode of claim 1, wherein the optical properties of the electrode can be adjusted by adjusting the length of the allotrope used.

9. The electrode of claim 1, further comprising at least one organic functional polymer.

10. A photovoltaic cell, comprising:
a first electrode including a first allotrope.

11. The photovoltaic cell of claim 10, wherein the first allotrope comprises nanotubes.

12. The photovoltaic cell of claim 11, wherein the nanotubes comprise carbon nanotubes.

13. The photovoltaic cell of claim 10, wherein the first allotrope comprises silicon.

14. The photovoltaic cell of claim 10, wherein the first allotrope comprises a spherical allotrope.

15. The photovoltaic cell of claim 10, wherein the first allotrope comprises a metallically conductive allotrope.

16. The photovoltaic cell of claim 10, wherein the first allotrope comprises a semiconductor.

17. The photovoltaic cell of claim 10, wherein the first electrode comprises a composite material including the first allotrope.

18. The photovoltaic cell of claim 10, wherein the first electrode further comprises an organic material.

19. The photovoltaic cell of claim 18, wherein the organic material is a conductive organic material.

20. The photovoltaic cell of claim 18, wherein the organic material is a semiconductor.

21. The photovoltaic cell of claim 18, wherein the organic material comprises a polymer.

22. The photovoltaic cell of claim 10, further comprising a substrate that supports the first allotrope.

23. The photovoltaic cell of claim 10, wherein the first electrode is transparent.

24. The photovoltaic cell of claim 10, further comprising a second electrode, the second electrode comprising a second allotrope.

25. The photovoltaic cell of claim 24, further comprising an organic semiconductor between the first and second electrodes.

26. The photovoltaic cell of claim 10, wherein the first electrode is an anode.

27. The photovoltaic cell of claim 10, wherein the first electrode is a cathode.

28. A photovoltaic cell, comprising:
a first electrode comprising nanotubes;
a second electrode; and
an organic semiconductor between the first and second electrodes.

29. The photovoltaic cell of claim 28, wherein the nanotubes comprise carbon nanotubes.

30. The photovoltaic cell of claim 28, wherein the first electrode comprises a composite material including the nanotubes.

31. The photovoltaic cell of claim 28, wherein the first electrode further comprises an organic material.

32. The photovoltaic cell of claim 31, wherein the organic material is a conductive organic material.

33. The photovoltaic cell of claim 31, wherein the organic material is a semiconductor.

34. The photovoltaic cell of claim 31, wherein the organic material comprises a polymer.

35. The photovoltaic cell of claim 28, further comprising a substrate that supports the first allotrope.

36. A photovoltaic cell, comprising:
a first electrode comprising silicon;
a second electrode; and
an organic semiconductor between the first and second electrodes.

37. The photovoltaic cell of claim 36, wherein the first electrode comprises a composite material including the silicon.

38. The photovoltaic cell of claim 36, wherein the first electrode further comprises an organic material.

39. The photovoltaic cell of claim 38, wherein the organic material is a conductive organic material.

40. The photovoltaic cell of claim 38, wherein the organic material is a semiconductor.

41. The photovoltaic cell of claim 38, wherein the organic material comprises a polymer.

42. The photovoltaic cell of claim 36, further comprising a substrate that supports the first allotrope.
